(19) United States
(12) Patent Application Publication
(10) Pub. No.: US 2012/0129322 A1
(43) Pub. Date: May 24, 2012

(54) COMPOSITE MATERIAL COMPRISING NANOPARTICLES AND PRODUCTION OF PHOTOACTIVE LAYERS CONTAINING QUATERNARY, PENTANARY AND HIGHER-ORDER COMPOSITE SEMICONDUCTOR NANOPARTICLES

(75) Inventors: Dieter Meissner, Wels (AT); Thomas Rath, Graz (AT); Eugen Maier, Graz (AT); Gregor Trimmel, Graz (AT); Albert Plessing, Nestelbach (AT); Franz Stelzer, Graz (AT)

(73) Assignee: ISOVOLTAIC AG, Lebring (AT)

(21) Appl. No.: 13/375,939

(22) PCT Filed: May 27, 2010
(86) PCT No.: PCT/AT2010/000184

§ 371 Date: Jan. 20, 2012

(30) Foreign Application Priority Data
Jun. 2, 2009 (AT) A 847/2009

(51) Int. Cl. H01L 21/20; H01B 1/00; H01B 1/12; B82Y 40/00; B82Y 30/00

(52) U.S. Cl. 438/478; 252/518.1; 252/519.3; 252/519.33; 977/773; 977/890; 257/E21.09

(57) ABSTRACT

A composite material includes at least two components, wherein at least one component is present in the form of nanoparticles, which consist of at least three metals and at least one non-metal and the diameter of which is less than one micrometre, preferably less than 200 nm. The novel composite material is particularly well suited for the production of photoactive layers.

The invention relates to a composite material comprising nonoparticles and the production of photoactive layers containing quaternary, pentanary and higher-order composite semiconductor nanoparticles. The invention further relates to the use of the aforementioned photoactive layers.

Quaternary, pentanary and higher-order, more complex composite nanoparticles have numerous important advantages compared to the usual binary and tertiary nanoparticles. On the one hand, it is possible by using quaternary nanoparticles to replace expensive and rare elements, such as indium for example, in copper indium sulphide by inexpensive, frequently occurring elements, such as zinc and tin for example. On the other hand, band gaps and also band positions can be adjusted very precisely on account of the higher number of material combinations. Binary and tertiary compounds offer only limited possibilities for this, whereas the use of quaternary and pentanary nanoparticles, through the possibility of combining a plurality of elements, is much more flexible with regard to the adjustment of specific properties.

Research has therefore been conducted for quite some time into the production of quaternary, pentanary and more complex chalcogenide compounds of the type Ib-IIb-IV-VI, because the latter are very interesting materials for extremely diverse optoelectronic applications, such as for example solar cells, sensors, detectors, switches and displays. For example, copper zinc tin sulphide (Cu₂ZnSnS₄, CZTS, kesterite), on account of the bandgap energy of 1.4-1.5 eV¹, which lies fairly close to the optimum value for a solar cell absorber material, and on account of a high absorption coefficient¹ of over 10⁴ cm⁻¹, is a highly promising and in particular inexpensive semiconductor material for the production of solar cells on a large scale. Furthermore, all the raw materials for producing this material are amply available in the Earth's crust (zinc: 75 ppm, tin: 2.2 ppm, by comparison indium: 0.049 ppm); that is to say that they are available and moreover non-toxic.¹

On account of these favourable material properties, a start was already made at the end of the 1980s to investigate this material with regard to photovoltaic applications.² A report concerning a CZTS solar cell was produced in 1988 by Ito Nakazawa³. Use was made here of a heterodiode comprising a conductive cadmium-tin-oxide layer and a sputtered CZTS layer on a steel substrate. By heat-treating this device, it was possible a year later⁴ to increase the photovoltage of 165 mV to 250 mV (short-circuit current: 0.1 mA/cm²). In 1997, Friedlmeier et al. produced CZTS by thermal vapour deposition. Degrees of efficiency of 2.3% and a photovoltage of 570 mV were reported for a solar cell made from this material and CdS/ZnO.⁵ CZTS was subsequently produced by RF magnetron sputtering⁶ and by gas-phase sulphurisation of precursors vapour-deposited by means of electron beam. The highest degree of efficiency for CZTS thin-layer solar cells reported to date amounts to 5.45%.⁷

In the aforementioned photovoltaic applications, CZTS was formed only after the layer formation by thermally induced crystallisation, wherein the layers, whilst containing crystallites which have grain boundaries with respect to one another, do not however contain crystals with saturated surfaces. This is of considerable importance for reducing recombination losses from charge carrier pairs generated in the materials.

Apart from the previously described production techniques, CZTS layers have also been produced using spray pyrolysis techniques. Madarasz et al⁸ synthesised thiourea complexes of CuCl, ZnCl₂ and SnCl₂ and produced CZTS layers with these starting compounds in aqueous solution. Kamoun et al.⁹ used an aqueous solution of CuCl, ZnCl₂, SnCl₄ and thiourea for the spray process. In both publications, the aqueous solutions are sprayed onto preheated substrates at temperatures between 225 and 360° C.

However, the production of quaternary and pentanary compounds is not trivial, and use is often made of complicated synthesis methods to produce the latter in a defined manner. Furthermore, there are no reports that nanocrystals comprising quaternary, such as CZTS for example, or pentanary chalcogenide compounds of the type Ib-IIb-IV-VI have been able to be produced in a defined stoichiometric composition in the sense of the invention claimed here. As already described above, an important factor here is the difference between crystallites in an initially completely disordered layer and crystallites with defined surfaces, such as do not arise in the case of the methods initially forming a homogeneous layer, such as vapour deposition, spraying, sputtering, CVD and PECVD, unless additional components in the layer form a defined matrix for arising (nano-)crystallites. Otherwise, defined crystal or nanocrystal surfaces arise only at the layer surfaces, such as were produced for example in the work by Kamoun et al.⁹ with AFM. Such surface structures, however, are not evidence of nanocrystallites, such as are the subject-matter of the invention here.

The semiconductors Cu₂FeSnS₄ (Ib-VIII-IV-VI) and Cu₂CoSnS₄ (Ib-IX-IV-VI) have already been produced by means of an expensive method in nanocrystalline form by An et al.¹⁰ by means of an autoclave synthesis from chlorides using thiourea as a sulphur source and water as a solvent. The reaction time amounted to 14 to 20 hours. The production method, however, differs fundamentally from the methods described here which are the subject-matter of this invention. An application for a composite has not hitherto been described.

The invention aims to provide a remedy here.

The invention relates to a composite material comprising at least two components, which is characterised in that one component is present in the form of nanoparticles, which consist of at least three metals and at least one non-metal and the diameter of which is less than one micrometre, preferably less than 200 nm. A quaternary composition results from the number of the elements, such as three metals combined with one non-metal. If, however, four metals and a further non-metal are used, a pentanary composition results.

Further advantageous embodiments of this composite material according to the invention are disclosed in sub-claims 2 to 6.

The invention further relates to photoactive layers comprising the composite material according to the invention, which are characterised in that at least one organic, electroactive copolymer or oligomer selected from the group of polythiophenes, polyparaphenylene vinylenes, polyfluorenes, polyparaphenylenes, polyanilines, polypyrroles, polyacetylenes, polycarbazoles, polyarylamines, polyisothianaphthenes, polybenzothiadiazoles and/or their derivatives is present as an organic, electroactive component. The photoactive layer according to the invention comprises as an inorganic, electroactive component nanoparticles which exhibit X-ray reflections with a marked broadening, i.e. enlargement of the half-value width of the reflections of the solid by at least 10%.

The invention further relates to a method for producing the photoactive layer according to the invention, which is characterised in that a coating solution of metal ions and at least one precursor is deposited on a surface which preferably has a temperature of less than 100° C.

Further advantageous embodiments of this method are disclosed according to the sub-claims.

The invention further relates to the use of the photoactive layer according to the invention for producing components with fluorescence properties as well as components or subassemblies with storage capacity such as solar cells, sensors or detectors, electrical or optical, including the UV, IR and microwave range, components, switches, displays or radiation-emitting components, such as lasers or LEDs.

The newly devised methods for quaternary, pentanary or more complex compounds of the type Ib-IIb-IV-VI are preeminently well suited, on account of the short reaction time, the simple, accessible starting compounds and the high material purity, for producing nanoparticles and, therefore, indirectly also for producing photovoltaically active layers. These synthesis methods only require reaction times of 20 min or 60 min, which represents an additional improvement on the method published by An et al.

In the devised synthesis routes, use is made on the one hand of simple metal salts, such as chlorides, bromides, iodides, nitrates, sulphates, acetates, acetyl acetonates, carbonates, formates, carbamates, thiocarbamates, xanthates, trithiocarbonates, phosphates, thiolates, thiocyanates, tartrates, ascorbates, phthalocyanines, elementary sulphur, selenium or tellurium, as a chalcogen source and oleylamine, dodecylamine or nonylamine or other amines as a solvent. Furthermore, sulphurous anions of the metal salts can also act as a sulphur source.

This method delivers multinary nanoparticles with uniform particle sizes around 5 nm and uniform particle shapes in defined stoichiometry.

On the other hand, multinary nanoparticle layers can also be produced directly in a matrix from simple metal salts, such as chlorides, bromides, iodides, nitrates, sulphates, acetates, acetyl acetonates, carbonates, formates, carbamates, thiocarbamates, xanthates, trithiocarbonates, phosphates, thiolates, thiocyanates, tartrates, ascorbates, phthalocyanines and a sulphur source, such as elementary sulphur, H₂S, sulphides, thioacetamide, thiourea or also anions of the used metal salts in pyridine or other organic solvents, such as for example acetone, methylethylketone, chloroform, toluene, chlorobenzene, THF or ethanol. Polymers, but also organic or inorganic compounds, can be used as a matrix.

Further advantages arise through the direct production of nanoparticles in a matrix. On account of their small diameter, nanoparticles have specific properties which are brought about by the quantisation, such as for example the change in the optical and electronic properties, which can only be obtained permanently if they do not grow, i.e. agglomerate. These special properties can therefore be better obtained in a fixed matrix, since the nanoparticles are much more stable here than for example in solution.

The synthesised nanoparticles are used to produce poly-crystalline layers from semiconductor materials, which are particularly well suited for photovoltaic applications. In this method, the nanoparticle solution is deposited on a substrate and thereafter heated, in order on the one hand to remove the organic stabiliser from the layer and on the other hand to sinter together the nanoparticles to form polycrystalline material for fluorescence applications and optoelectronic applications.

Furthermore, the syntheses presented here can be used to produce photoactive layers comprising a mixture of these nanoparticles with an organic electroactive component—this can on the one hand be a lower—molecular electroactive organic compound, or an electroactive polymer. As an alternative, the nanoparticles can be produced by a thermally induced reaction directly in the electroactive component following the coating step. The organic components act in such mixtures as electron donors and hole conductors, the nanoparticles as electron acceptors and electron conductors.

The invention is explained in greater detail below with the aid of possible examples of embodiment for performing the invention:

### EXAMPLE 1

### Synthesis of Cu₂ZnSnS₄ Nanoparticles in Solution for Producing Polycrystalline Semiconductor Layers

1 mmol (190.5 mg) CuI, 0.5 mmol (68.1 mg) ZnCl₂ and 0.5 mmol (313.2 mg) SnI₄ are dissolved in 10 ml oleylamine (alternative: dodecylamine, nonylamine). 6 mmol (192.4 mg) sulphur (sublimated) dissolved in 3 ml oleylamine (alternative: dodecylamine, nonylamine) is then added, and the solution is heated up to 220° C. for 60 min. For the purpose of purification, the particles are precipitated in methanol after cooling of the reaction solution and then centrifuged off. The obtained nanoparticles are dried at 60° C. and are then soluble for further analyses or tests in various solvents, such as chloroform, dichloromethane, toluene or hexane.

The nanoparticle solution is deposited on a substrate, and the arising layer is then heated up to 500° C. for 2 hours. A polycrystalline layer is thereby formed.

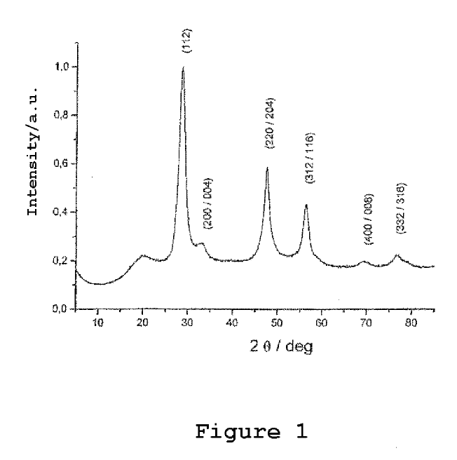

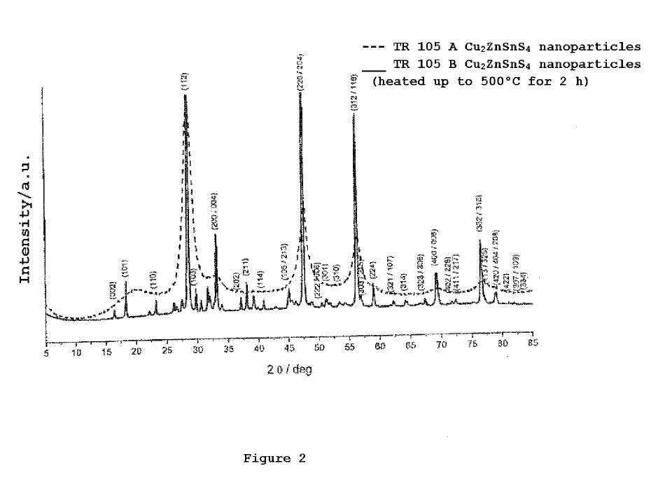

The diffractograms of the nanoparticles (TR 105 A) and the polycrystalline layer (TR 105 B) are represented in FIG. 1 and FIG. 2 respectively. FIG. 1 shows the XRD analysis of Cu₂ZnSnS₄ nanoparticles and FIG. 2 shows the XRD analysis of Cu₂ZnSnS₄ nanoparticles (A) directly after the synthesis and (B) after 2 h of heat treatment at 500° C. The broad peaks at 28.4° (112), 32.9° (200/004), 47.3° (220/204), 56.1° (312/116), 69.1° (400/008) and 76.3° (332/316) originate from the reflections of the kesterite of greatest intensity, the broad peak around 20° originating from the stabiliser oleylamine still present in the sample. After the heat treatment of this nanoparticle layer for 2 hours at 500° C., an XRD analysis was again carried out (see FIG. 2, TR 105B). The peaks are markedly sharper as a result of the sintering together of the primary crystallites—the primary crystallite size increases from approx. 5 to approx. 30 nm, and all the characteristic reflections¹¹ of Cu₂ZnSnS₄ are present. Furthermore, the still present oleylamine is evaporated or decomposed by the heat treatment and the peak at 20° thus completely disappears. Highly pure thin polycrystalline layers can thus be produced with this method.

For the particles which were analysed directly after the synthesis, a primary crystallite size of 5.6 nm was obtained by the Debye-Scherrer formula. The primary crystallite size increases to −30 nm in the case of the heat-treated nanoparticles.

The XRD analyses unequivocally demonstrate that the produced nanoparticles are quaternary CZTS particles (crystalline structure: kesterite).

Furthermore, CZTS nanoparticles were produced with the following synthesis parameters (see table 1);

TABLE 1
Parameters of further CZTS nanoparticle
syntheses

| | | Reaction |
|---|---|---|
| Solvent | Reaction time/hours | temperature/° C. |
| Oleylamine | 1 | 220 |
| Oleylamine | 8 | 160 |
| dodecylamine | 1 | 220 |
| dodecylamine | 9 | 120 |
| nonylamine | 1 | 200 |
| nonylamine | 12 | 120 |

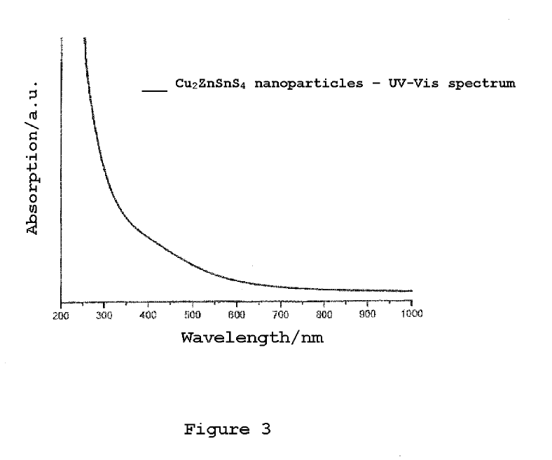

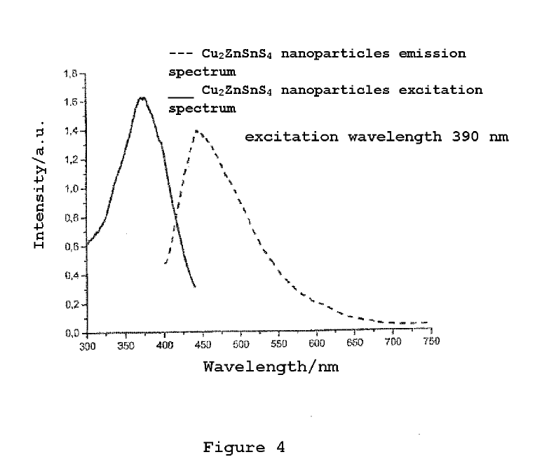

Furthermore, the obtained nanoparticles were investigated using optical methods such as UV-Vis spectroscopy and fluorescence spectroscopy. The UV-Vis spectrum of the Cu₂ZnSnS₄ nanoparticles, dissolved in hexane, is represented in FIG. 3 and shows that the nanoparticle solution begins to absorb slightly from approx. 850 nm, which corresponds to the bandgap of CZTS. A sharper rise in the absorption can be detected from 650 nm. The emission and excitation spectra in FIG. 4 show that the produced CZTS nanoparticles, i.e. Cu₂ZnSnS₄ nanoparticles dissolved in hexane, exhibit a marked fluorescence with a maximum at 445 nm.

### EXAMPLE 2

### Production of Cu₂ZnSnS₄ Nanoparticle Layers

0.165 mmol (20.2 mg) CuAc, 0.0825 mmol (18.1 mg) ZnAc₂, 0.0825 mmol (29.3 mg) SnAc₄ and 1.65 mmol (125.6 mg) thiourea were dissolved in an ultrasound bath in 2 ml pyridine. The faint yellowish solution is applied dropwise onto a glass substrate. Alternatively, the solution was also deposited by means of spray techniques, such as airbrushing.

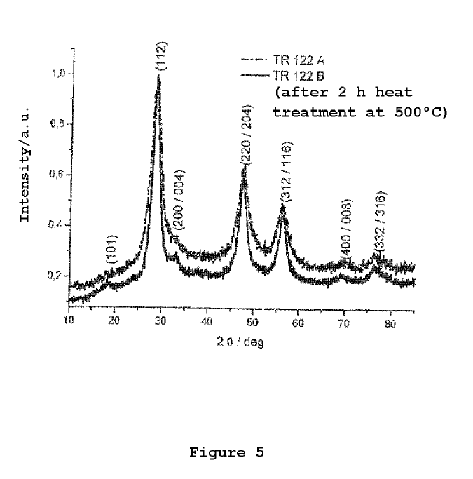

The layers thus obtained were heated under an inert gas atmosphere up to 100° C. for 8 min, to 150° for 8 min and to 200° C. for 8 min. The layer becomes reddish in colour, then brown and finally black. The material thus obtained was analysed by X-ray diffractometry. FIG. 5 shows diffractograms of the formed CZTS layer (A) after heat treatment at 200° C. and (B) after heat treatment at 500° C.

The broad peaks at 28.4° (112), 47.3° (220/204), 56.1° (312/116), 69.1° (400/008) and 76.3° (332/316) originate from the reflections of the Cu₂ZnSnS₄ of greatest intensity. The primary crystallite size ascertained by the Debye-Scherrer relationship amounts to 3.5 nm.

If sample 2 is heat-treated at 500° C. for 2 hours, the primary crystallite size becomes somewhat larger (5 nm), the peak width narrower, and further characteristic peaks appear at 18.2° (101) and 32.9° (220/004).

Furthermore, it is also possible to produce this synthesis with chlorides or iodides as starting compounds, and to use thioacetamide instead of thiourea as a sulphur source.

### EXAMPLE 3

### Production of a poly-3-hexylthiophene (P3HT)/Cu₂ZnSnS₄-bulk heterojunction solar cell

The Cu₂ZnSnS₄ nanoparticles obtained in the synthesis from example 1 are used in combination with the electroactive polymer P3HT as a donor for the active layer of a nanocomposite solar cell. For this purpose, excess stabiliser (oleylamine) is first removed by ligand exchange with pyridine carried out three times. A P3HT/Cu₂ZnSnS₄ solution is then produced in chloroform (polymer concentration 4 mg/ml; nanoparticle concentration: 12 mg/ml).

The solar cell is built up layer by layer on an ITO-coated glass substrate. As the first layer, polyethylene-dioxythiophene: polystyrene-sulfonate (PEDOT:PSS) is deposited by spin coating to smooth the ITO electrode. The deposited layer is dried under inert gas at approx. 80° C. The active layer (P3HT/Cu₂ZnSnS₄ solution in chloroform) is deposited again by spin coating as the next step. Following a further drying step (15 min, 150° C.) under inert gas, the production of the solar cell is completed with the thermal vapour deposition from the metal electrode (aluminium).

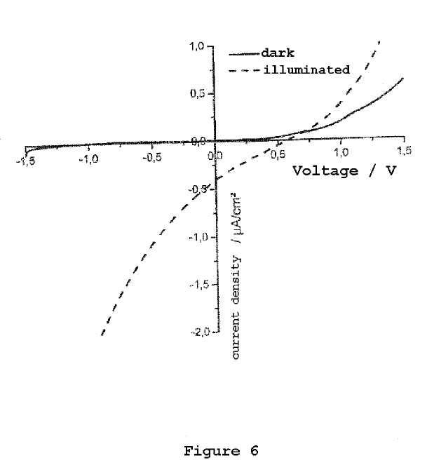

Typical current/voltage characteristic curves of the obtained P3HT/Cu₂ZnSnS₄—bulk heterojunction solar cell are represented in FIG. 6.

The short-circuit current of this cell is still fairly small due to the still relatively high proportion of oleylamine in the nanoparticles, but it can be increased by a further optimisation of the ligand exchange. The achieved photovoltage of 570 mV, which is brought about by the combination of the materials P3HT and Cu₂ZnSnS₄, is essential.

### EXAMPLE 4

### Production of a Polyparaphenylene-vinylene (PPV)/Cu₂ZnSnS₄—Bulk Heterojunction Solar Cell

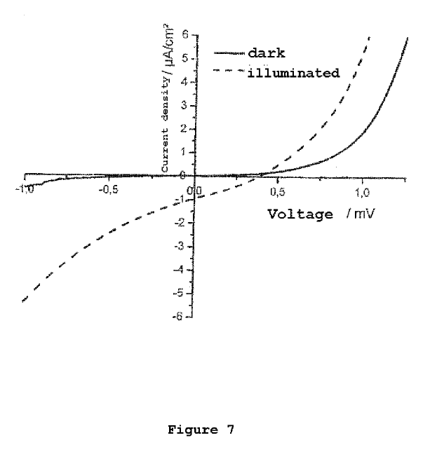

In order to produce a PPV/Cu₂ZnSnS₄ bulk heterojunction solar cell, a PPV layer is deposited on an ITO-coated glass substrate in order to avoid short-circuits. For this purpose, an aqueous PPV (polyparaphenylene-vinylene) precursor solution (poly(p-xylene tetrahydrothiophenium chloride)) is applied dropwise onto the substrate and heated up to 160° C. for 15 min. A PPV/Cu₂ZnSnS₄ precursor solution (mixture of 2 ml PPV precursor (2.5 mg/ml) with a PPV/Cu₂ZnSnS₄ nanoparticle precursor (17.3 mg CuI, 6.6 mg ZnCl₂, 20.8 mg SnAc₄, 68.4 mg TTA, 2 ml pyridine) is then produced, diluted 1:10, applied dropwise onto the PPV layer and heated up to 160° C. for 15 min under an inert gas atmosphere. The PPV/Cu₂ZnSnS₄ nanocomposite layer, which serves as the active layer in the solar cell, is thereby formed. The solar cell is finished by vapour deposition from aluminium electrodes. As can be seen from the current/voltage characteristic curves in FIG. 7, the PPV/Cu₂ZnSnS₄—bulk heterojunction solar cell has a photovoltage of 389 mV and a photocurrent density of 1.0 μA/cm².

To sum up, it can be said that the nanoparticles according to the invention, on account of their quaternary, pentanary or even higher-order composition, are very well suited for the formation of polycrystalline layers with semiconductor properties.

On account of the produced synergetic effects, extremely satisfactory results are accordingly achieved in the desired applications, such as in photovoltaics.

### CITED REFERENCES FROM THE LITERATURE

¹H. Katagiri, N. Sasaguchi, S. Hando, S. Hoshino, J. Ohashi, T. Yokota, Sol. Energy Mater. Sol. Cells 49 (1997) 407-413.
²H. Katagiri, Thin Solid Films 480-481 (2005) 426-432.
³K. Ito T. Nakazawa, Jpn. J. Appl. Phys. 27 (1998) 2094.
⁴K. Ito, T. Nakazawa, Proceedings of the 4^{th} International Conference of Photovoltaic Science and Engineering, Sydney, 1989, page 341.
⁵Th. Friedlmeier, N. Wieser, T. Walter, H. Dittrich, H.-W. Schock, Proceedings of the 14^{th} European Conference of Photovoltaic Science and Engineering and Exhibition, Bedford, 1997, page 1242.
⁶J. S. Seol, S. Y. Lee, J. C. Lee, H. D. Nam, K. H. Kim, Sol. Energy Mater. Sol. Cells 75 (2003) 155.
⁷H. Katagiri, K. Jimbo, K. Moriya, K. Tschuchida, Proceedings of the 3^{rd} World Conference on Photovoltaic Solar Energy Conversion, Osaka, 2003, page 2874.
⁸J. Madarasz, P. Vombicz, M. Okuya, S. Kaneko, Solid State Ionics 141-142 (2001) 439.
⁹N. Kamoun, H. Bouzouita, B. Rezig, Thin Solid Films 515 (2007) 5949-5952.
¹⁰C. An, K. Tang, G. Shen, C. Wang, L. Huang, Y. Qian, MRS Bulletin 38 (2003) 823-830.
¹¹W. Schäfer, R. Nitsche, Mat. Res. Bull. 9 (1974) 645-654.

1. A composite material comprising at least two components, characterised in that at least one component is present in the form of nanoparticles, which consist of at least three metals and at least one non-metal and the diameter of which is less than one micrometre, preferably less than 200 nm.

2. The composite material according to claim 1, characterised in that the nanoparticles are present in crystalline form, and that their X-ray reflections are characterised by a marked broadening.

3. The composite material according to claim 1, characterised in that the size of the nanoparticles can be determined electron-microscopically.

4. The composite material according to claim 1, characterised in that the nanoparticles are embedded in a matrix comprising at least one other component of the composite material.

5. The composite material according to claim 1, characterised in that the composite material contains at least one organic compound.

6. The composite material according to claim 1, characterised in that the nanoparticles are present in at least one other component of the composite material in a concentration which is sufficient for continuous, conductive paths to arise between the nanoparticles and the other component.

7. A photoactive layer comprising a composite material according to claim 1, characterised in that at least one organic, electroactive polymer, copolymer or oligomer selected from the group of polythiophenes, polyparaphenylene vinylenes, polyfluorenes, polyparaphenylenes, polyanilines, polypyrroles, polyacetylenes, polycarbazoles, polyarylamines, polyisothianaphthenes, polybenzothiadiazoles and/or their derivatives is present as an organic, electroactive component.

8. The photoactive layer according to claim 7, characterised in that the inorganic, electroactive component is present in the form of nanoparticles, which exhibit X-ray reflections with a marked broadening, i.e. enlargement of the half-value width of the reflections of the solid by at least 10%.

9. A method for producing photoactive layers according to claim 7, characterised in that a coating solution of metal ions and at least one precursor is deposited on a surface.

10. The method according to claim 9, characterised in that the coating solution contains nanoparticles of a quaternary, pentanary or higher-order compound, which consists of at least 3 metals and at least one non-metal, wherein the coating solution is deposited on a surface which has a temperature of less than 100° C.

11. The method according to claim 9, characterised in that the production of the photoactive layer takes place at normal pressure with a reaction time of less than 12 hours.

12. The method according to claim 9, characterised in that the coating solution contains nanoparticles of a quaternary and/or pentanary compound, which consists of at least 3 metals and at least one non-metal, and that the coating solution is stabilised by an organic compound with the function of a capper and is deposited on a surface.

13. The method according to claim 9, characterised in that the precursor solution comprises a chalcogenide and is deposited by means of spray techniques onto a substrate which has a temperature of less than 100° C.

14. The method according to claim 9, characterised in that the photoactive layer is subsequently subjected to a further heat treatment in the temperature range from 40° C. to 1000° C., preferably 40° C. to 400° C.

15. The method according to claim 9, characterised in that at least one component is present in the coating solution in the form of nanoparticles, the size of which can be determined electron-microscopically.

16. The method according to claim 9, characterised in that at least one component is present in the coating solution in the form of nanoparticles, which are characterised in that they contain at least one element of the I. subgroup, preferably Cu, Ag, Au.

17. The method according to claim 9, characterised in that at least one component is present in the coating solution in the form of nanoparticles, which are characterised in that they contain at least one element of the II. subgroup, preferably Zn, Cd, Hg.

18. The method according to claim 9 characterised in that at least one component is present in the coating solution in the form of nanoparticles, which are characterised in that they contain at least one element of the IV. subgroup, preferably C, Si, Ge, Sn, Pb.

19. The method according to claim 9, characterised in that at least one component is present in the coating solution in the form of nanoparticles, which are characterised in that they contain an element of the chalcogen group, preferably 0, S, Se, Te, Po.

20-21. (canceled)
